(19) United States
(12) Patent Application Publication
(10) Pub. No.: US 2004/0159923 A1
(43) Pub. Date: Aug. 19, 2004

(54) Using benzocyclobutene based polymers as underfill materials

(76) Inventors: Sergei Skokov, San Jose, CA (US); Lei Jiang, Aloha, OR (US); Sadasivan Shankar, Cupertino, CA (US)

Correspondence Address: Timothy N. Trop, TROP, PRUNER & HU, P.C., STE 100, 8554 KATY FWY, HOUSTON, TX, 77024-1841, US

(21) Appl. No.: 10/367,266

(22) Filed: Feb. 15, 2003

(51) Int. Cl. H01L 23/02

(52) U.S. Cl. 257/678

(57) ABSTRACT

A cyclotene chemical structure may be modified to reduce its curing temperature. With the reduced curing temperature, the material may be highly advantageous as an underfill material for surface nonpackaging.

### BACKGROUND

This invention relates generally to semiconductor integrated circuits and, particularly, to packages for those integrated circuits.

Integrated circuits are typically assembled into packages that are mounted to a printed circuit board. The package may include a substrate that has solder balls or other types of contacts that are attached to the circuit board. An integrated circuit is mounted to the substrate. The substrate may having routing traces or vias that electrically couple the integrated circuit to the solder balls.

The integrated circuit may be coupled to corresponding surface pads on the substrate with solder bumps or balls in a process commonly referred to as controlled collapse chip connection (C4). The substrate coefficient of thermal expansion is different than the coefficient of thermal expansion for the integrated circuit. When the package is thermally cycled, the difference in thermal expansion may create a mechanical strain in the solder bumps. This strain may create cracks and corresponding electrical opens in the solder bumps, particularly after a number of thermal cycles.

Many surface mounted packages, such as C4 packages, contain an underfill material that is formed between the integrated circuit and the substrate. The underfill material structurally reinforces the solder bumps and improves the life and reliability of the package. The underfill material is typically dispensed onto the substrate in a liquid or semi-liquid form. The liquid underfill then flows between the integrated circuit and the substrate under capillary action. The liquid underfill eventually is cured to a solid state.

The underfill process may completely fill the space between the integrated circuit and the substrate to structurally reinforce the solder bumps. A number of techniques have been developed to ensure that the underfill material surrounds the solder bumps. The lower the coefficient of thermal expansion, the higher the mechanical strength and the higher the glass transition temperature the better the underfill material.

Thus, there is a need for improved materials to act as underfill materials in surface mount packages.

### BRIEF DESCRIPTION OF THE DRAWINGS

FIG. 1 is partial enlarged cross-sectional view through one embodiment of the present invention;

FIGS. 2A-2D show chemical structures in accordance with several embodiments of the present invention;

FIG. 3 shows a chemical structure in accordance with another embodiment of the present invention;

FIG. 4 is a flow chart in accordance with one embodiment of the present invention; and

FIG. 5 is a graph of gel time versus temperature for various embodiments of the present invention.

### DETAILED DESCRIPTION

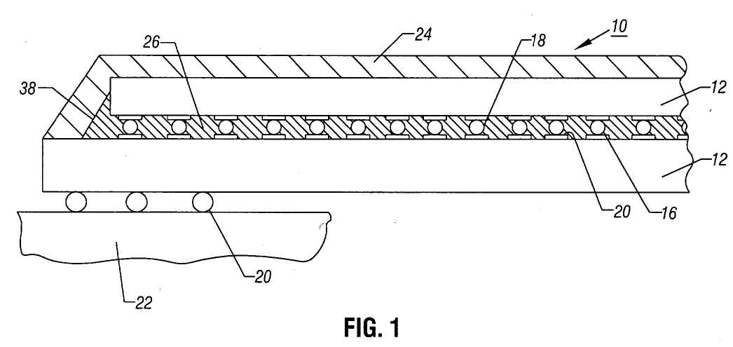

Referring to FIG. 1, a surface mount package 10 may include an integrated circuit 12 mounted to a packaged substrate 14. The package 10 may further include a plurality of solder bumps 16 that are coupled to die pads 18 of the integrated circuit 12 and corresponding conductive surface pads of the substrate 14. The solder bumps 16 may be assembled using a process commonly referred to as controlled collapse chip connection (C4) in one embodiment of the present invention.

The package 10 may include a plurality of solder balls 20 that are attached to the substrate 14. The solder balls 20 may be reflowed to attach the package to the substrate 22. The packaged substrate 14 may have routing traces or vias (not shown) that electrically couple the solder bumps 16 to the solder balls 20. The integrated circuit 12 may be enclosed by an encapsulant or heat spreader 24.

The package 10 may also include an underfill material 26 that is located at the interface of the integrated circuit 12 and the substrate 14. The underfill 26 may be a benzocyclobutene (BCB) based polymer in accordance with one embodiment of the present invention.

BCB based polymers possess an attractive combination of mechanical and electrical properties, such as a relatively low coefficient of thermal expansion, relatively high mechanical strength, relatively high value of glass transition temperature, and a relatively low dielectric constant. These properties make BCB polymers attractive materials for the underfill 26.

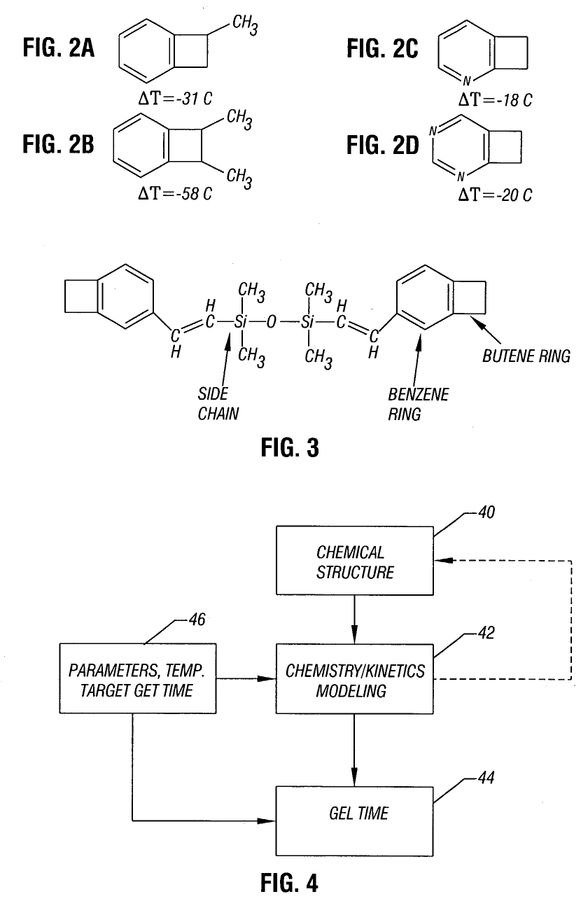

However, the curing temperature for BCB polymers typically exceeds 200° C. The use of such a high temperature significantly limits the application of BCB based materials. For example, the curing temperature of epoxy based materials with hardeners that are typically used as underfill materials is typically around 100° C. By using the chemical substructures shown in FIGS. 2A-2D, the curing temperature of the BCB may be reduced compared to the curing temperature of the cyclotene or BCB base structure shown in FIG. 3.

Referring to FIG. 3, starting with the cyclotene chemical structure shown in FIG. 3, for a thermosetting resin, a chemistry/kinetics modeling simulation tool 42 is utilized. All relevant chemical reactions are identified and their rates are computed. Curing is initialized by opening the butene ring as shown in FIGS. 2A-2D. Network formation is due to reactions between ethylene fragments in side chains and fragments of the open butene rings.

Next, the reaction rates, initial chemical concentrations, and desired value of process temperatures are utilized to analyze curing kinetics and predict curing time. The outputs from the chemistry/kinetics simulation tool is a gelation time as indicated in block 44. The dashed lines in FIG. 4, between the simulation and chemical structure, indicate that information is passed about the rate limiting step back into the chemical structure module. In other words, structure optimization was focused on compounds that will lead to a speed up of the ring opening reaction, while the structure of the side chains was kept unchanged here.

Four compounds, shown in FIGS. 2A-2D, lead to significant decreases in curing temperatures as indicated. Note that for simplicity, side chains are not shown, and they are assumed to be identical to the side chain of the cyclotene shown in FIG. 3. Also, all four positions of the nitrogen atom in the benzene ring lead to very similar decreases in curing temperature. In addition, having to use a flourine instead of methyl groups leads to a decrease in curing temperature to a smaller extent.

The substructure shown in FIGS. 2A and 2B include methyl groups in a butene ring, while the structures shown in FIGS. 2C and 2D include nitrogen atoms in a benzene ring. Thus, by simply adding methyl groups to the butene ring, indicated in FIG. 3, curing temperature may be reduced. Similarly, adding nitrogen to the benzene ring, as indicated in FIG. 3, reduces curing temperature.

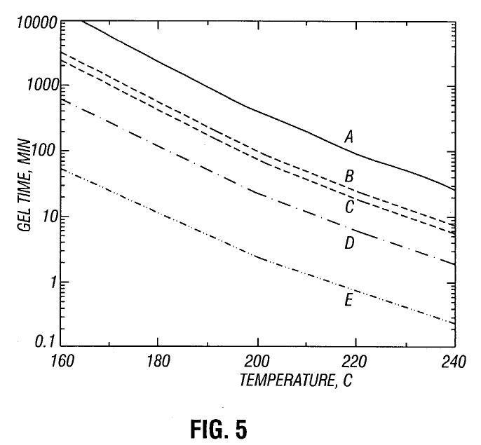

Referring to FIG. 5, the results of a kinetic Monte Carlo (KMC) simulation is provided in terms of gelation time in minutes versus temperature in degrees C. The gelation or gel time decreases significantly for the materials shown in FIGS. 2A-2D. The curve A is for cyclotene, and the curves B and C are for one and two nitrogen heteroatoms, indicated in FIGS. 2C and 2D. The curves D and E are for the one and two CH₃ groups as shown in FIGS. 2A and 2B. The compound with two CH₃ groups, indicated at E, can be cured at 160° C. in less than one hour.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a material including cyclotene; and
modifying the cyclotene to reduce the curing temperature.

2. The method of claim 1 wherein modifying the cyclotene includes inserting nitrogen in the benzene ring of the cyclotene.

3. The method of claim 1 wherein modifying the cyclotene includes attaching a methyl group to the butene ring.

4. The method of claim 1 wherein modifying the cyclotene includes adding two methyl groups to the butene ring.

5. The method of claim 1 including forming an underfill.

6. The method of claim 5 including applying the underfill to a semiconductor integrated circuit surface mount package.

7. A packaged integrated circuit comprising:
an integrated circuit die;
a surface mount connection between said die and said package; and
underfill within said package, said underfill including benzocyclobutene modified to reduce its curing temperature.

8. The circuit of claim 7 wherein said benzocyclobutene includes methyl groups attached to a butene ring.

9. The circuit of claim 7 wherein said benzocyclobutene includes nitrogen in a benzene ring.

10. The circuit of claim 7 wherein said benzocyclobutene includes two methyl groups attached to a single butene ring.

11. The circuit of claim 1 wherein said surface mount connection is a controlled collapse chip connection.

12. An underfill comprising:
a cyclotene material wherein said cyclotene is modified to reduce its curing temperature.

13. The underfill of claim 12 wherein said cyclotene includes a benzene ring having substituted nitrogen.

14. The underfill of claim 13 wherein said cyclotene includes a butene ring with attached methyl group.

15. The underfill of claim 12 wherein said cyclobutene includes a butene ring with at least two methyl groups attached.

16. A method comprising:
modifying cyclotene to insert nitrogen in the benzene ring of cyclotene.

17. The method of claim 16 including reducing the curing temperature of said cyclotene by modifying said cyclotene.

18. The method of claim 12 including forming an underfill.

19. A method comprising:
attaching a methyl group to the butene ring of cyclotene.

20. The method of claim 19 including attaching two methyl groups to the same butene ring of cyclotene.

21. The method of claim 19 including reducing the curing temperature of cyclotene by modifying said cyclotene.

22. The method of claim 19 including forming an underfill.
